(19) United States
(12) Patent Application Publication
(10) Pub. No.: US 2011/0156800 A1
(43) Pub. Date: Jun. 30, 2011

(54) SENSOR, SENSING METHOD THEREOF, AND FILTER THEREFOR

(75) Inventors: Jei-Hyuk Lee, Yongin-si (KR); Ju-Min Lee, Yongin-si (KR); Jae-Surk Hong, Yongin-si (KR); Byung-Joon Moon, Yongin-si (KR); Duck-Young Jung, Yongin-si (KR)

(73) Assignee: ATLab Inc., Yongin-si (KR)

(21) Appl. No.: 13/062,061

(22) PCT Filed: Feb. 20, 2009
(86) PCT No.: PCT/KR2009/000824

§ 371 Date: Mar. 3, 2011

(30) Foreign Application Priority Data
Sep. 19, 2008 (KR) 10-2008-0092336

(51) Int. Cl. H03K 17/945; H03K 5/00

(52) U.S. Cl. 327/517; 327/551

(57) ABSTRACT

A sensor, a sensing method of the sensor, and a filter of the sensor are provided. The sensor includes a sensing data output unit configured to output sensing data that varies depending on touch or proximity of an object, and a determiner configured to compare a threshold value with the sensing data to recognize touch or proximity, vary a first strength value indicating the sensing data in a state of no touch or no proximity and a second strength value indicating the sensing data in a state of touch or proximity, vary the threshold value using the first and second strength values, and output an output signal indicating touch or proximity.

### BACKGROUND OF THE INVENTION

1. Field of the Invention

The present invention relates to a sensor, and more particularly, to a sensor capable of recognizing touch or proximity with a given sensitivity, a sensing method of the sensor, and a filter of the sensor.

2. Description of the Related Art

A sensor capable of detecting touch or proximity of a touch object such as a finger or pen and outputting a touch or proximity result is increasingly used in household electrical appliances, computing devices, and portable communication terminals.

Korean Patent Registration No. 666699 discloses a touch sensor capable of recognizing touch by a touch object by obtaining a delay time difference between a sensing signal and a reference signal using the capacitance of the touch object. Korean Patent Publication No. 2008-50544 discloses a delay measuring circuit capable of measuring the delay time difference between the sensing signal and the reference signal.

The touch sensor may be constructed to recognize being touched by the touch object when a delay time difference between the reference signal, whose delay time does not vary depending on touch, and the sensing signal, whose delay time varies depending on touch, is longer than a reference time, and to recognize not being touched by the touch object when the delay time difference is shorter than the reference time. However, even when the touch sensor is in a touch state by the touch object, delay time may vary with environment changes such as interference noise, detecting location, cover thickness, and/or touch pad type, and thus the delay time difference also may vary. Accordingly, when a conventional touch sensor attempts to recognize touch in the above-described manner, since touch sensitivity varies according to the foregoing conditions, it is necessary to perform a tuning operation of adjusting the reference time in consideration of the conditions. In particular, the tuning operation is unavoidable during product development. Since electrical conditions between touch spots and touch sensors vary from product to product, the tuning operation involves repeatedly changing hardware and modifying software. Therefore, product development time is extended due to the tuning operation.

### SUMMARY OF THE INVENTION

The present invention is directed to a sensor capable of shortening a tuning operation necessarily required in product development and maintaining a given sensitivity irrespective of environment, etc. when a user uses a product.

The present invention is also directed to a sensing method of the sensor.

The present invention is also directed to a filter of the sensor.

One aspect of the present invention provides a sensor including: a sensing data output unit configured to output a sensing data that varies depending on touch or proximity of an object; and a determiner configured to compare a threshold value with the sensing data to recognize touch or proximity, vary a first strength value indicating the sensing data in a state of no touch or no proximity and a second strength value indicating the sensing data in a state of touch or proximity, vary the threshold value using the first and second strength values, and output an output signal indicating touch or proximity.

The sensing data output unit may measure impedance that varies depending on touch or proximity and output a value corresponding to the measured impedance as the sensing data. The sensing data output unit may include: a sensing signal output unit configured to output a reference signal and a sensing signal delayed by a predetermined time with respect to the reference signal depending on touch or proximity; and a delay time measurement unit configured to detect a delay time difference between the sensing signal and the reference signal and output delay data corresponding to the delay time difference as the sensing data.

The sensing signal output unit of the sensing data output unit may include: a reference clock generator configured to generate a reference clock signal; a reference signal generator configured to receive the reference clock signal and output the reference signal; and a sensing signal generator including a pad and configured to delay the reference clock signal when the object touches or approaches the pad and output the sensing signal.

The delay time measurement unit of the sensing data output unit may include: a delay chain unit including a plurality of delay elements connected in cascade and configured to output, in response to the reference signal, a plurality of delay signals having different delay times and an iteration counting signal indicating the number of times the reference signal is fed back; an edge detector configured to output a reset signal in response to the reference signal, output a counting stop signal in response to the sensing signal, and output a code signal corresponding to the number of edges of the delay signals; and a decoder configured to decode the iteration counting signal and the code signal and output the delay data corresponding to the delay time difference between the reference signal and the sensing signal.

The delay chain unit of the delay time measurement unit may include: a switch configured to perform a logical AND operation on the delay signal, the counting stop signal, and a feedback signal and output a first delay signal of the delay signals; a delay chain including the delay elements configured to receive the first delay signal, delay the first delay signal, and each output a corresponding one of the delay signals; an inverter configured to invert a final delay signal output by a final delay element of the delay elements and output the feedback signal; and a counter configured to be reset in response to the reset signal and to count edges of the feedback signal to generate the iteration counting signal and output the iteration counting signal to the decoder in response to the counting stop signal.

The determiner of the sensor may include: a filter unit configured to receive the sensing data and output a sensing value; a strength determiner configured to vary and output the first strength value without varying the second strength value in a state of no touch or no proximity using the sensing value and to vary and output the second strength value without varying the first strength value in a state of touch or proximity using the sensing value; and a decider configured to receive the first and second strength values to calculate the threshold value, compare the threshold value with the sensing value to decide whether there is touch or proximity, and output the output signal.

The filter unit of the determiner may include: a first linear filter configured to receive the sensing data at a first sampling rate, remove noise from the sensing data, and output first filtered data; a nonlinear filter configured to receive the first filtered data, restrict variation within a predetermined range or combine a plurality of samples, and output second filtered data; and a second linear filter configured to receive the second filtered data at a second sampling rate that is lower than the first sampling rate, remove noise from the second filtered data, and output the sensing value.

Each of the first and second linear filters may be a low-pass filter (LPF) or a band-pass filter (BPF).

The strength determiner of the determiner may change the first strength value to the sensing value when a present first strength value is 0, and change the second strength value to a value obtained by adding a predetermined first value to the sensing value when the second strength value is 0.

According to an exemplary embodiment, in a state of no touch or no proximity, the strength determiner may maintain the first strength value when the sensing value varies during a predetermined first time, and change the first strength value to the sensing value when the sensing value does not vary during the first time. According to another exemplary embodiment, in a state of no touch or no proximity, the strength determiner may maintain the first strength value when the second strength value is less than a predetermined second value, and change the first strength value to the sensing value when the second strength value is greater than the second value. According to still another exemplary embodiment, in a state of no touch or no proximity, the strength determiner may maintain the first strength value when a difference between the first strength value and the sensing value is less than a predetermined third value, and change the first strength value to the sensing value when the difference between the first strength value and the sensing value is greater than the third value. In the above-described embodiments, the strength determiner may change the first strength value to the sensing value or change the first strength value to a value obtained by adding a predetermined fourth value to the first strength value when the first strength value is greater than the sensing value, and change the first strength value to a value obtained by subtracting the fourth value from the first strength value when the first strength value is less than the sensing value.

According to an exemplary embodiment, in a state of touch or proximity, the strength determiner may maintain the second strength value when the sensing value varies during a predetermined second time, and change the second strength value to the sensing value when the sensing value does not vary during the second time. According to another exemplary embodiment, in a state of touch or proximity, the strength determiner may change the second strength value to the sensing value when the second strength value is greater than a value obtained by adding a predetermined fifth value to the first strength value, and change the second strength value to the value obtained by adding the fifth value to the first strength value when the second strength value is less than the value obtained by adding the fifth value to the first strength value.

The decider of the determiner may include: a threshold value calculator configured to receive the first and second strength values and calculate the threshold value; and a touch decider configured to compare the threshold value with the sensing value to decide whether there is touch or proximity and output the output signal based on the decision result.

According to an exemplary embodiment, the threshold value may include a first threshold value obtained by adding a predetermined first offset value to the threshold value and a second threshold value obtained by subtracting a predetermined second offset value from the threshold value, and the threshold value calculator may output the first threshold value and the second threshold value. Also, the touch decider may decide that there is touch or proximity when the sensing value becomes greater than the first threshold value in a state of no touch or no proximity, and decide that there is no touch or no proximity when the sensing value becomes less than the second threshold value in a state of touch or proximity.

According to another exemplary embodiment, the decider may decide that there is touch or proximity when the sensing value is greater than the threshold value for a third time in a state of no touch or no proximity, and decide that there is no touch or no proximity when the sensing value is less than the threshold value for a fourth time that is shorter than the third time in a state of touch or proximity.

According to still another exemplary embodiment, the decider may receive the first strength value, the second strength value, and the sensing value, decide that there is touch or proximity when the sensing value becomes greater than a value obtained by adding a predetermined sixth value to the first strength value in a state of no touch or no proximity, decide that there is no touch or no proximity when the sensing value becomes less than a value obtained by subtracting a predetermined seventh value from the second strength value in a state of touch or proximity, and output the output signal based on the decision result.

The determiner of the sensor may further include an activity detector configured to receive the sensing value, determine that the sensor is inactive when the sensing value is within a predetermined range for a predetermined time, and enable a control signal. The strength determiner and/or the decider may stop operating when the control signal is enabled. In this case, the sensor may externally output the control signal and control operation of an external input apparatus.

The determiner of the sensor may further include an activity detector configured to receive the output signal, detect if tapping occurs, and generate a wake-up signal when tapping is detected. In this case, the sensor may externally output the wake-up signal and wake up an external input apparatus.

Another aspect of the present invention provides a sensing method including: a sensing value calculating step of calculating a sensing value that varies depending on touch or proximity of an object; an initialization step of changing the first strength value to the sensing value when a first strength value is 0, and changing the second strength value to a value obtained by adding a predetermined first value to the sensing value when a second strength value is 0; a first strength value varying step of receiving the sensing value and varying the first strength value in a state of no touch or no proximity; a second strength value varying step of receiving the sensing value and varying the second strength value in a state of touch or proximity; a threshold value calculating step of receiving the first and second strength values and calculating a threshold value; and a recognition step of comparing the sensing value with the threshold value and recognizing touch or proximity.

The sensing value may correspond to impedance that varies depending on touch or proximity of the object. Alternatively, the sensing value may correspond to a delay time difference between a reference signal and a sensing signal that is delayed by a predetermined time with respect to the reference signal in a state of touch or proximity of the object.

According to an exemplary embodiment, the first strength value varying step may include maintaining the first strength value when the sensing value varies during a predetermined first time, and changing the first strength value to the sensing value when the sensing value does not vary during the first time. According to another exemplary embodiment, the first strength value varying step may include maintaining the first strength value when the second strength value is less than a predetermined second value, and changing the first strength value to the sensing value when the second strength value is greater than the second value. According to another exemplary embodiment, the first strength value varying step may include maintaining the first strength value when a difference between the first strength value and the sensing value is less than a predetermined third value, and changing the first strength value to the sensing value when the difference between the first strength value and the sensing value is greater than the third value. According to the above-described exemplary embodiments, the first strength value varying step may include changing the first strength value to the sensing value or changing the first strength value to a value obtained by adding a predetermined fourth value to the first strength value when the first strength value is greater than the sensing value, and changing the first strength value to a value obtained by subtracting the fourth value from the first strength value when the first strength value is less than the sensing value.

According to an exemplary embodiment, the second strength value varying step may include maintaining the second strength value when the sensing value varies during a predetermined second time and changing the second strength value to the sensing value when the sensing value does not vary during the second time. According to another exemplary embodiment, the second strength value varying step may include changing the second strength value to the sensing value when the second strength value is greater than a value obtained by adding a predetermined fifth value to the first strength value, and changing the second strength value to the value obtained by adding the fifth value to the first strength value when the second strength value is less than the value obtained by adding the fifth value to the first strength value.

According to an exemplary embodiment, the recognition step may include recognizing the state of touch or proximity when the sensing value is greater than the threshold value for a third time in a state of no touch or no proximity, and recognizing the state of no touch or no proximity when the sensing value is less than the threshold value for a fourth time that is shorter than the third time. According to another exemplary embodiment, the threshold value may include a first threshold value and a second threshold value, the threshold value calculating step may include calculating the first threshold value by adding a predetermined first offset value to the threshold value and calculating the second threshold value by subtracting a predetermined second offset value from the threshold value, and the recognition step may include recognizing the state of touch or proximity when the sensing value becomes greater than the first threshold value in a state of no touch or no proximity, and recognizing the state of no touch or no proximity when the sensing value becomes less than the second threshold value in a state of touch or proximity.

Still another aspect of the present invention provides a filter of a sensor including: a first linear filter configured to receive sensing data that varies depending on touch or proximity at a first sampling rate, remove noise from the sensing data, and output first filtered data; and a second filter connected in cascade to the first linear filter and configured to receive the first filtered data, filter the first filtered data, and output second filtered data.

According to an exemplary embodiment, the second filter may be a nonlinear filter configured to receive the first filtered data, restrict variation within a sample or combine a plurality of samples, and output the second filtered data. According to another exemplary embodiment, the second filter may be a second linear filter configured to receive the first filtered data at a second sampling rate that is lower than the first sampling rate, remove noise from the first filtered data, and output the second filtered data.

The filter may include the first linear filter, the nonlinear filter, and a second linear filter configured to receive the second filtered data at a second sampling rate that is lower than the first sampling rate, remove noise from the second filtered data, and output the sensing value.

Each of the first and second linear filters may be an LPF or a BPF.

### BRIEF DESCRIPTION OF THE DRAWINGS

FIG. 1 shows the constitution of a touch sensor according to an exemplary embodiment of the present invention.

FIG. 2 shows the constitution of a sensing signal output unit of the touch sensor shown in FIG. 1 according to an exemplary embodiment of the present invention.

FIG. 3 shows the constitution of a delay time measurement unit of the touch sensor shown in FIG. 1 according to an exemplary embodiment of the present invention.

FIG. 4 shows the constitution of a touch determiner of the touch sensor shown in FIG. 1 according to an exemplary embodiment of the present invention.

FIG. 5 shows the constitution of a filter unit of the touch determiner shown in FIG. 4 according to an exemplary embodiment of the present invention.

FIG. 6 is a flowchart illustrating a method of determining a first strength value of a strength determiner of the touch determiner shown in FIG. 4.

FIG. 7 is a timing diagram illustrating the method of determining the first strength value shown in FIG. 6.

FIG. 8 is a flowchart illustrating a method of determining a second strength value using the strength determiner of the touch determiner shown in FIG. 4.

FIG. 9 is a timing diagram illustrating the method of determining the second strength value shown in FIG. 8.

FIG. 10 shows the constitution of a decider of the touch determiner shown in FIG. 4 according to an exemplary embodiment of the present invention.

FIG. 11 is a timing diagram illustrating operation of the decider shown in FIG. 10.

FIG. 12 shows the constitution of a touch determiner of the touch sensor shown in FIG. 1, according to another exemplary embodiment of the present invention.

### DETAILED DESCRIPTION OF THE INVENTION

Hereinafter, a sensor, a sensing method of the sensor, and a filter of the sensor according to exemplary embodiments of the present invention will be described in detail with reference to the attached drawings.

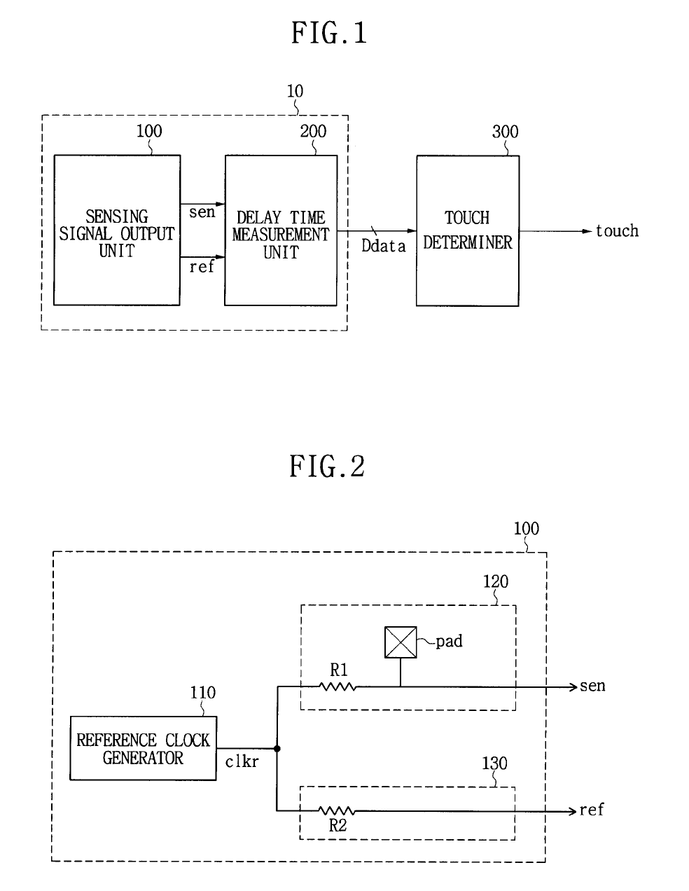

FIG. 1 shows the constitution of a sensor according to an exemplary embodiment of the present invention. The sensor includes a sensing data output unit 10 and a touch determiner 300, and the sensing data output unit 10 includes a sensing signal output unit 100 and a delay time measurement unit 200.

Functions of the blocks shown in FIG. 1 will now be described.

The sensing data output unit 10 outputs sensing data Ddata that varies depending on touch by a touch object. The sensing signal output unit 100 outputs a reference signal “ref” and a sensing signal “sen” that is delayed with respect to the reference signal “ref” depending on touch of the touch object. The delay time measurement unit 200 detects a delay time difference between the sensing signal “sen” and the reference signal “ref” and outputs delay data corresponding to the delay time difference as the sensing data Ddata.

The touch determiner 300 determines that touch by the touch object has occurred using the sensing data Ddata and outputs a touch signal “touch” indicating whether touch has occurred based on the determination result. Specifically, the touch determiner 300 varies a threshold value using the sensing data Ddata, determines that touch has occurred when the sensing data Ddata is greater than the threshold value, determines that no touch has occurred when the sensing data Ddata is less than the threshold value, and outputs the touch signal “touch” depending on whether touch has occurred. The threshold value may be calculated using a first strength value and/or a second strength value. The first strength value, which is an strength value when no touch has occurred, may correspond to a delay time difference between the sensing signal “sen” and the reference signal “ref” in a no-touch state, and the second strength value, which is a strength value when in a touch state, may correspond to a delay time difference between the sensing signal “sen” and the reference signal “ref”. The first and second strength values may be calculated by the touch determiner 300 using the sensing data Ddata. Also, the threshold value may include a first threshold value and a second threshold value. The touch determiner 300 may be constructed to determine that touch has occurred when the sensing data Ddata is greater than the first threshold value and determine that no touch has occurred when the sensing data Ddata is less than the second threshold value.

Although not shown in the drawings, the sensing data output unit may measure impedance (e.g., capacitance) that varies depending on touch of the touch object, and output a value corresponding to the measured impedance (e.g., capacitance) as the sensing data Ddata.

FIG. 2 shows the constitution of the sensing signal output unit of the sensor shown in FIG. 1 according to an exemplary embodiment of the present invention. The sensing signal output unit includes a reference clock generator 110, a sensing signal generator 120, and a reference signal generator 130. The sensing signal generator 120 includes a resistor R1 and a pad “pad”, and the reference signal generator 130 includes a resistor R2.

Functions of the blocks shown in FIG. 2 will now be described.

The reference clock generator 110 outputs a reference clock signal “clkr”. The sensing signal generator 120 delays the reference clock signal “clkr” and outputs the delayed reference clock signal as a sensing signal “sen” when a touch object touches the pad “pad”, and outputs the reference clock signal “clkr” without delaying the reference clock signal “clkr” as the sensing signal “sen” when the touch object does not touch the pad “pad”. Specifically, when a touch object having a predetermined capacitance touches the pad “pad”, the reference clock signal “clkr” applied to the sensing signal generator 120 is delayed by some time due to the resistor R1 and the capacitance of the touch object and output as the sensing signal “sen”. In contrast, when no touch object touches the pad “pad”, the reference clock signal “clkr” is not delayed and output as is as the sensing signal “sen”. The reference signal generator 130 does not delay the reference clock signal “clkr” transmitted from the reference clock generator 110 and outputs the reference clock signal “clkr” as is as the reference signal “ref”.

Although not shown in the drawings, the reference signal generator 130 may further include a capacitor connected between a terminal through which the reference signal “ref” is output and a ground voltage to delay the reference clock signal “clkr” by a predetermined time irrespective of touch of the touch object and output the delayed reference clock signal as the reference signal “ref”.

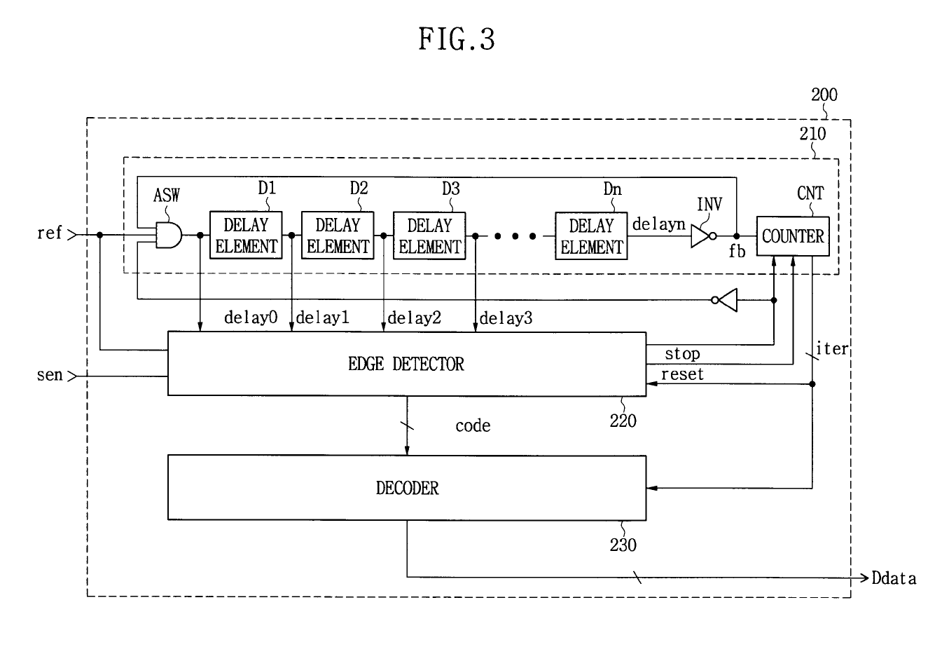

FIG. 3 shows the constitution of the delay time measurement unit of the sensor shown in FIG. 1 according to an exemplary embodiment of the present invention. The delay time measurement unit 200 includes a delay chain unit 210, an edge detector 220, and a decoder 230. The delay chain unit 210 includes a switch ASW embodied by a 3-input AND gate, a plurality of delay elements D1, D2, . . . , and Dn connected in cascade, an inverter INV, and a counter CNT.

Functions of the blocks shown in FIG. 3 will now be described.

The delay chain unit 210 outputs a plurality of delay signals “delay0”, “delay1”, . . . having different delay times and an iteration counting signal “iter” in response to a reference signal “ref”. The iteration counting signal “iter” indicates the number of times the reference signal “ref” is fed back through the delay chain unit 210. The switch ASW outputs the delay signal “delay0”(i.e. the first delay signal of the plurality of delay signals) as an input signal in response to the reference signal “ref”, a feedback signal “fb”, and a counting stop signal “stop”. Specifically, the switch ASW performs a logical AND operation on the reference signal “ref”, the feedback signal “fb”, and the counting stop signal “stop”, generates the delay signal “delay0”, and outputs the delay signal “delay0” as an input signal to the delay chain unit 210 having the delay elements D1, D2, . . . , and Dn. The delay elements D1, D2, . . . , and Dn delay the input delay signal “delay0” and output delay signals “delay1”, “delay2”, . . . , and “delayn”, respectively. The inverter INV inverts the delay signal “delayn”(i.e. the final delay signal of the plurality of delay signals) output by the final delay cell Dn of the delay chain unit 210 and outputs the feedback signal “fb”. The counter CNT outputs the iteration counting signal “iter”, which indicates the number of times the reference signal “ref” is fed back through the delay chain unit 210, in response to the feedback signal “fb”. Specifically, the counter CNT counts edges of the feedback signal “fb” obtained by inverting the delay signal “delayn” and outputs the iteration counting signal “iter”. Also, the counter CNT is reset in response to a reset signal “reset” output by the edge detector 220, stops counting in response to a counting stop signal “stop” output by the edge detector 220, and outputs the iteration counting signal “iter” to the decoder 230. Alternatively, the counter CNT may be reset in response to the counting stop signal “stop” output by the edge detector 220.

That is, the delay chain unit 210 starts operating in response to the reference signal “ref” indicating the beginning of measurement of delay time. The delay chain unit 210 receives the delay signal “delay0” generated by performing a logical AND operation on the reference signal “ref”, the feedback signal “fb”, and the counting stop signal “stop”, delays the delay signal “delay0” by predetermined times, and outputs a plurality of delay signals “delay1”, “delay2”, . . . , and “delayn” having different delay times. The counter CNT outputs the iteration counting signal “iter”. Also, the delay chain unit 210 stops operating in response to the counting stop signal “stop” output by the edge detector 220.

The edge detector 220 outputs the reset signal “reset” in response to the reference signal “ref”, outputs the counting stop signal “stop” in response to the sensing signal “sen”, counts the edges of the delay signals “delay0”, “delay1”, . . ., and “delayn-1”, and outputs a code signal “code” corresponding to the number of edges of the delay signals “delay0”, “delay1”, . . . , and “delayn-1”. Also, the edge detector 220 is reset in response to the iteration counting signal “iter”. In other words, when a value of the iteration counting signal “iter” is changed, the edge detector 220 is reset.

The decoder 230 decodes the code signal “code” output by the edge detector 220 and the iteration counting signal “iter” output by the counter CNT, generates delay data, and outputs the delay data as sensing data Ddata.

The delay time measurement unit 200 may be constructed in various other manners than the exemplary embodiment shown in FIG. 3. For example, the switch ASW may be embodied by a switch circuit which selectively outputs a reference signal “ref” and a feedback signal “fb” in response to an iteration counting signal “iter”. Also, the counter CNT and the decoder 230 may be omitted from the delay time measurement unit 200 shown in FIG. 3, and the edge detector 220 may start counting the number of edges of the delay signals “delay0”, “delay1”, . . . , and “delayn-1” in response to the reference signal “ref”, stop counting the number of edges of the delay signals “delay0”, “delay1”, . . . , and “delayn-1” in response to the sensing signal “sen”, and output delay data Ddata corresponding to the number of edges of the delay signals “delay0”, “delay1”, . . . , and “delayn-1”. In addition, the edge detector 220 may be replaced by a code generator including a plurality of exclusive OR (XOR) gates and a plurality of AND gates. The XOR gates may output the delay signals “delay0”, “delay1”, . . . , and “delayn-1” as they are or invert the delay signals “delay0”, “delay1”, . . . , and “delayn-1” in response to the iteration counting signal “iter” and output inverted signals as comparison signals. Also, the AND gates may perform a logical AND operation on the comparison signals and a sensing signal “sen” and output code signals “code”, respectively. Furthermore, although FIG. 3 illustrates the delay chain unit 210 having a feedback construction, a delay chain without a feedback construction may also be adopted.

FIGS. 2 and 3 illustrate examples of a delay-type touch sensor, but the present invention is not limited thereto. That is, the present invention may also be applied to a sensor capable of sensing impedance (e.g., capacitance) that varies depending on touch. In this case, the delay time measurement unit 200 may be replaced by an impedance measurement unit which measures the impedance (e.g., capacitance) using a pad, converts the measured impedance (e.g., capacitance) into a digital value, and outputs the digital value. The impedance measurement unit may be provided in various forms. For instance, the impedance measurement unit may measure a charging/discharging time determined by impedance (e.g., capacitance) that varies depending on touch, convert the charging/discharging time into a digital value, and output the digital value. In this case, the charging/discharging time may be converted into a digital value using a delta-sigma analog-to-digital converter (ADC).

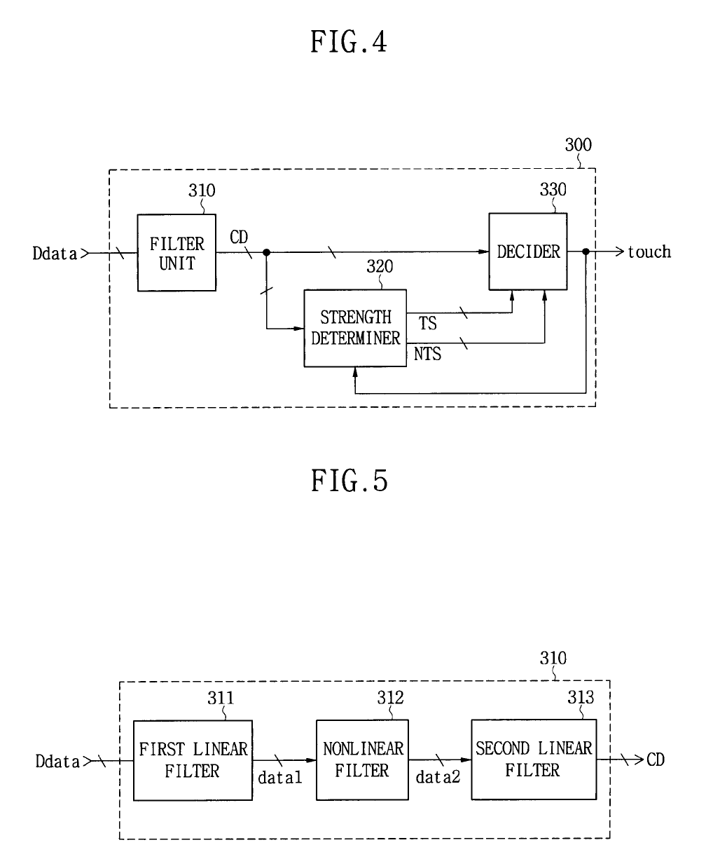

FIG. 4 shows the constitution of the touch determiner of the sensor shown in FIG. 1 according to an exemplary embodiment of the present invention. The touch determiner 300 includes a filter unit 310, an strength determiner 320, and a decider 330.

Functions of the blocks shown in FIG. 4 will now be described.

The filter unit 310 filters the sensing data Ddata generated by the delay time measurement unit 200 and outputs a delay value CD. The filter unit 310 may include a low-pass filter (LPF) or a band-pass filter (BPF) and remove noise. The strength determiner 320 varies a strength value when a touch object does not touch the pad “pad”, that is, a first strength value NTS corresponding to a delay time difference between the sensing signal “sen” and the reference signal “ref” in a no-touch state, using the delay value CD output by the filter unit 310, varies a strength value when the touch object touches the pad “pad”, that is, a second strength value TS corresponding to a delay time difference between the sensing signal “sen” and the reference signal “ref” in a touch state, using the delay value CD, and outputs the first and second strength values NTS and TS. Alternatively, the strength determiner 320 may determine whether touch has occurred in response to the touch signal “touch” output by the decider 330. The decider 330 decides that touch has occurred using the delay value CD output by the filter unit 310 and the first and second strength values NTS and TS output by the strength determiner 320 and outputs the touch signal “touch” indicating whether touch has occurred. Specifically, the decider 330 may determine a threshold value using the first and second strength values NTS and TS output by the strength determiner 320 and compare the delay value CD output by the filter unit 310 with the threshold value. Thus, the decider 330 may decide that touch has occurred when the delay value CD is greater than or equal to the threshold value, and decide that no touch has occurred when the delay value CD is less than the threshold value.

Although not shown in the drawings, according to circumstances, the filter unit 310 of the touch determiner 300 may output the sensing data Ddata as is without filtering as the delay value CD. In other words, the strength determiner 320 and the decider 330 of the touch determiner 300 may use the sensing data Ddata output by the delay time measurement unit 200 as is as the delay value CD.

As described above, although FIG. 4 illustrates examples of a delay-type touch sensor, the present invention may also be applied to a sensor capable of measuring impedance (e.g., capacitance). In this case, the filter unit 310 may receive sensing data Ddata obtained by converting the measured impedance (e.g., capacitance) into a digital value instead of delay data corresponding to a delay time difference between the sensing signal “sen” and the reference signal “ref”, and output a sensing value obtained by removing noise from the sensing data Ddata. Also, the strength determiner 320 may vary the first and second strength values NTS and TS using the sensing value output by the filter unit 310.

FIG. 5 shows the constitution of the filter unit of the touch determiner 300 shown in FIG. 4 according to an exemplary embodiment of the present invention. The filter unit 310 includes a first linear filter 311, a nonlinear filter 312, and a second linear filter 313.

Functions of the blocks shown in FIG. 5 will now be described. The first linear filter 311 samples delay data Ddata at a first sampling rate of, for example, 100 kHz, removes noise from the delay data Ddata, and outputs first filtered data “data1”. The nonlinear filter 312 may receive the first filtered data “data1” at a predetermined sampling rate, restrict variation within a predetermined range, and output second filtered data “data2”. Alternatively, the nonlinear filter 312 may replaced with an arithmetic unit such as accumulation. For an example of accumulation unit, the nonlinear filter 312 receive the first filtered data “data1”, combine a plurality of samples (e.g., 8 or 64 samples), and output the second filtered data “data2”. Alternatively, the nonlinear filter 312 may perform all of the above processes and output the second filtered data “data2”. The second linear filter 313 samples the second filtered data “data2” at a second sampling rate of, for example, 1 kHz, which is lower than the first sampling rate, removes noise from the second filtered data “data2”, and outputs a delay value CD. By controlling the sampling rate of the second linear filter 313 to be lower than that of the first linear filter 311, beating caused by an interference signal can be prevented.

In FIG. 5, the first and second linear filters 311 and 313 may be low-pass filters (LPFs) to remove high-frequency components from the delay data Ddata and the second filtered data “data2”, respectively. According to circumstances, both the first linear filter 311 and second linear filters 313 (or either the first linear filter 311 and second linear filters 313) may also be band-pass filters (BPFs) in order to remove specific frequencies of interference.

Although not shown in the drawings, the filter unit 310 of the touch determiner 300 may include only part of the first linear filter 311, the nonlinear filter 312, and the second linear filter 313. In this case, the first filtered data “data1” or the second filtered data “data2” may be output as the delay value CD.

That is, by use of the filter unit 310 shown in FIG. 5, the strength determiner 320 may determine the first and second strength values NTS and TS based on a precise delay value CD. Although FIG. 5 illustrates an example of a delay-type touch sensor, the filter unit 310 shown in FIG. 5 may also be applied to a touch sensor capable of measuring impedance (e.g., capacitance). In this case, the sensing value output by the filter unit 310 may not be the delay value CD corresponding to a delay time difference between the reference signal “ref” and the sensing signal “sen” but a value corresponding to the measured impedance (e.g., capacitance).

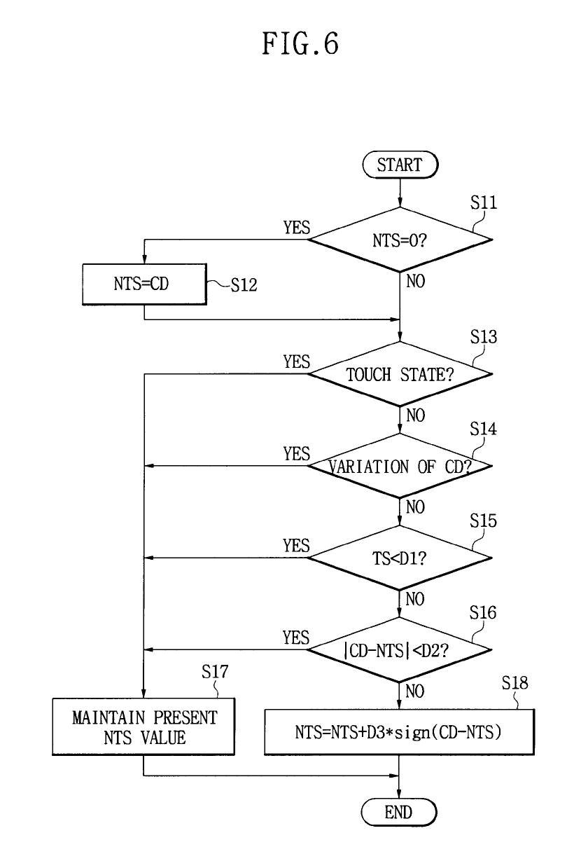

FIG. 6 is a flowchart illustrating a method of determining the first strength value NTS of the strength determiner 320 of the touch determiner 300 of the sensor of the present invention shown in FIG. 4 according to an exemplary embodiment of the present invention.

The method of determining the first strength value NTS using the strength determiner 320 will now be described with reference to FIG. 6.

To begin with, the strength determiner 320 determines whether a present first strength value NTS is 0 in step S11. When the present first strength value NTS is 0, the strength determiner 320 stores a present delay value CD received from the filter unit 310 as a new first strength value in step S12. When an power voltage is initially applied or the sensor is reset, the first strength value NTS may be 0. In this case, the first strength value NTS may be initialized to the present delay value CD.

Next, in step S13, the strength determiner 320 determines whether the touch sensor is in a touch state in response to a touch signal “touch” output by the decider 330 of the touch determiner 300. When the touch sensor is in a touch state, since it is unnecessary to change the first strength value indicating strength value when it is not in a touch state, the strength determiner 320 maintains the present first strength value NTS in step S17.

When it is determined in step S13 that the touch sensor is not in a touch state, the strength determiner 320 determines whether the delay value CD output by the filter unit 310 varies during a predetermined first time of, for example, about 12 ms, in step S14. When the delay value CD varies during the first time, the strength determiner 320 maintains the present first strength value NTS in step S17. Accordingly, the strength determiner 320 may prevent the first strength value NTS from being changed due to variation of the delay value CD caused by ambient noise, and it may vary the first strength value NTS when the delay value CD in a no-touch state varies due to environmental variation (e.g., temperature) or cover thickness variation.

In step S15, the strength determiner 320 determines whether the second strength value TS indicating the strength value when in a touch state is less than a predetermined first value D1. When the second strength value TS is less than the first value D1, the strength determiner 320 maintains the present first strength value NTS in step S17. Accordingly, the strength determiner 320 may be constructed to vary the first strength value NTS only after the second strength value TS becomes greater than the first value D1.

In step S16, the strength determiner 320 determines whether a difference between the delay value CD output by the filter unit 310 and the first strength value NTS is less than a predetermined second value D2. When the difference between the delay value CD and the first strength value NTS is less than the second value D2, the strength determiner 320 maintains the present first strength value NTS in step S17. In other words, when the difference between the delay value CD and the first strength value NTS is less than the second value D2, since the influence of external factors is immaterial, the strength determiner 320 may maintain the present first strength value NTS.

When the difference between the delay value CD and the first strength value NTS is greater than the second value D2, the strength determiner 320 adds a predetermined third value D3 to the present first strength value NTS or subtracts the third value D3 from the present first strength value NTS and stores an obtained value as a new first strength value NTS in step S18. Specifically, when the delay value CD is greater than the first strength value NTS by the second value D2 or more, the strength determiner 320 stores a value obtained by adding the third value D3 to the present first strength value NTS as the new first strength value NTS. Also, when the delay value CD is less than the first strength value NTS by the second value D2 or more, the strength determiner 320 stores a value obtained by subtracting the third value D3 from the present first strength value NTS as the new first strength value NTS.

FIG. 6 illustrates an example in which the strength determiner 320 sequentially determines whether the delay value CD varies during the predetermined first time in step S14, whether the second strength value TS is less than the predetermined first value D1 in step S15, and whether the difference between the delay value CD and the first strength value NTS is less than the predetermined second value D2 in step S16. However, in another exemplary embodiment, the strength determiner 320 may undergo only one of steps S14 through S16 and maintain or change the first strength value NTS. For example, the strength determiner 320 may determine only whether the delay value CD varies during the first time, maintain the first strength value NTS when the delay value CD varies during the first time, and vary the first strength value NTS when the delay value CD does not vary during the first time. Also, the order of steps S14 through S16 is not limited to the above-described embodiment and may be changed.

Also, FIG. 6 illustrates an example in which the first strength value NTS is changed by adding the predetermined third value D3 to the present first strength value NTS or subtracting the third value D3 from the present first strength value NTS. However, the strength determiner 320 may store the present delay value CD as the new first strength value NTS.

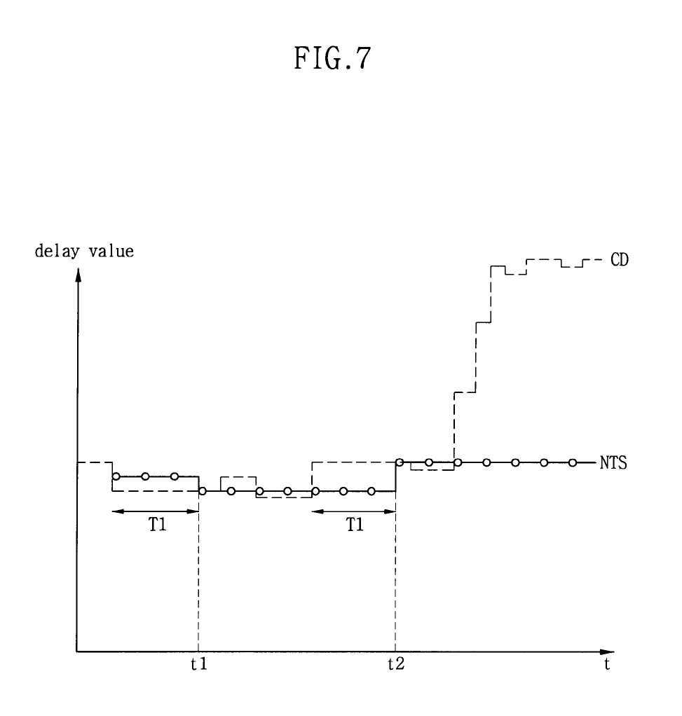

FIG. 7 is a timing diagram illustrating the method of determining the first strength value NTS of the strength determiner 320 of the touch determiner 300 of the sensor of the present invention shown in FIG. 6. Specifically, FIG. 7 illustrates a case where steps S15 and S16 are omitted from the method of FIG. 6 and the present delay value CD is stored as the new first strength value NTS in step S18 of FIG. 6. In FIG. 7, the delay value CD output by the filter unit 310 is illustrated with a dotted line, and the first strength value NTS is illustrated with a solid line.

The method of determining the first strength value NTS of the strength determiner 320 will now be described with reference to FIG. 7.

At a time point t1, since the delay value CD does not vary during a first time T1, the strength determiner 320 stores the delay value CD at the time point t1 as a new first strength value NTS. Thereafter, since the delay value CD is not maintained for the first time T1 before a time point t2, the strength determiner 320 does not vary the first strength value NTS. At the time point t2, since the delay value CD does not vary during the first time T1, the strength determiner 320 stores the delay value CD at the time point t2 as a new first strength value NTS again. After the time point t2, the delay value CD sharply jumps, meaning that the touch sensor is in a touch state. Thus, the strength determiner 320 does not vary the first strength value NTS after the time point t2.

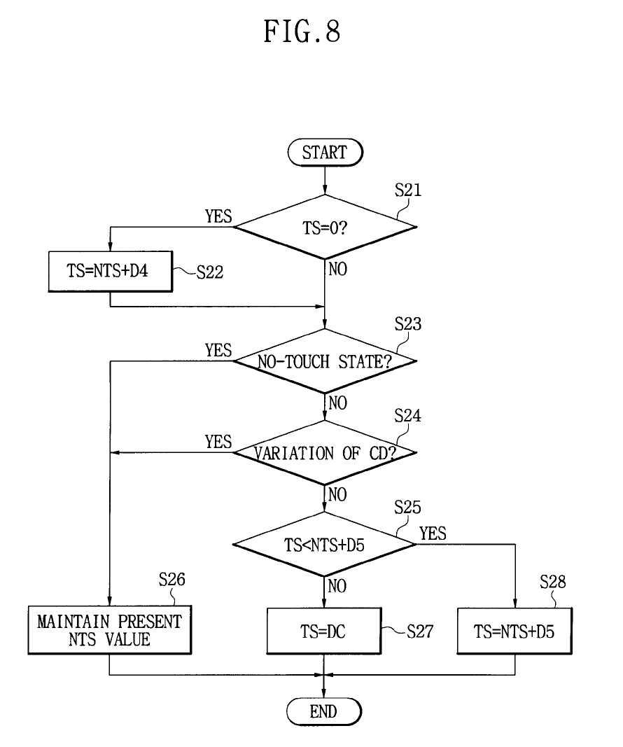

FIG. 8 is a flowchart illustrating a method of determining the second strength value TS of the strength determiner 320 of the touch determiner 300 of the sensor of the present invention shown in FIG. 4 according to an exemplary embodiment of the present invention.

The method of determining the second strength value TS will now be described with reference to FIG. 8.

To begin with, the strength determiner 320 determines if the second strength value TS is 0 in step S21. When the second strength value TS is 0, the strength determiner 320 stores a value obtained by adding a predetermined fourth value D4 to the first strength value NTS as a new second strength value TS in step S22. When an power voltage is initially applied or the sensor is reset, the second strength value TS may be 0. In this case, the second strength value TS may be initialized to the value obtained by adding the predetermined fourth value D4 to the first strength value NTS.

Next, the strength determiner 320 determines whether the touch sensor is in a touch state in response to the touch signal “touch” output by the decider 330 in step S23. When the touch sensor is not in a touch state, since it is unnecessary to change the second strength value TS indicating a strength value when in a touch state, the strength determiner 320 maintains the present second strength value TS in step S26.

In step S24, the strength determiner 320 determines whether the delay value CD output by the filter unit 310 varies during a predetermined second time of, for example, 7 ms. When the delay value CD varies during the second time, the strength determiner 320 maintains the present second strength value TS in step S26. Accordingly, the strength determiner 320 may prevent the second strength value TS from being changed due to variation of the delay value CD caused by ambient noise, and it may vary the second strength value TS when the delay value CD in a touch state varies due to environmental variation (e.g., temperature) or cover thickness variation. The second time may be controlled to be shorter than the first time mentioned in step S14 of FIG. 6. That is, the second strength value TS is changed in a touch state as described above. Since noise occurs due to a touch object in a touch state, it is necessary to maintain a specific delay value CD for a shorter time than when the strength determiner 320 determines the first strength value NTS that is changed in a no-touch state.

In step S25, the strength determiner 320 determine whether the second strength value TS is less than a value obtained by adding a predetermined fifth value D5 to the first strength value NTS. In other words, the strength determiner 320 determines whether a difference between the first and second strength values is greater than the predetermined fifth value D5. When the second strength value TS is less than the value obtained by adding the fifth value D5 to the first strength value NTS, the strength determiner 320 stores the value obtained by adding the fifth value D5 to the first strength value NTS as a new second strength value TS in step S28. Accordingly, the strength determiner 320 may determine the first and second strength values NTS and TS such that a difference between the first and second strength values NTS and TS becomes the fifth value D5 or more.

When the second strength value TS is greater than the value obtained by adding the fifth value D5 to the first strength value NTS, the strength determiner 320 stores the present delay value CD as the second strength value TS in step S27.

In another exemplary embodiment, the strength determiner 320 may determine the second strength value TS by omitting steps S25 and S28 from the process of FIG. 8. Specifically, the strength determiner 320 may determine only whether the touch sensor is touched or not in step S23 and whether the delay value CD is varied in step S24, to maintain the present second strength value TS or store the present delay value CD as a new second strength value TS.

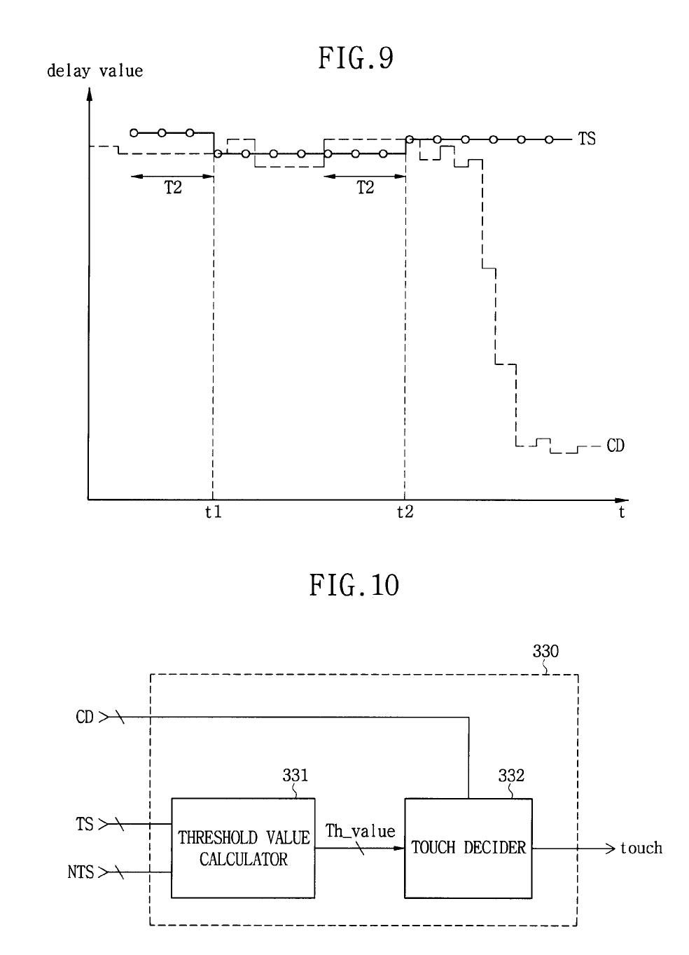

FIG. 9 is a timing diagram illustrating the method of determining the second strength value TS shown in FIG. 8. Specifically, FIG. 9 illustrates a case where steps S25 and S28 are omitted from the method of FIG. 6. In FIG. 9, the delay value CD output by the filter unit 310 is illustrated with a dotted line, and the second strength value TS is illustrated with a solid line.

The method of determining the second strength value TS will now be described with reference to FIG. 9.

At a time point t1, since the delay value CD does not vary during a predetermined second time T2, the strength determiner 320 stores the delay value CD at the time point t1 as a new second strength value TS. Thereafter, since the delay value CD is not maintained for the second time T2 before a time point t2, the strength determiner 320 does not vary the second strength value TS. At the time point t2, since the delay value CD does not vary during the second time T2, the strength determiner 320 stores the delay value CD at the time point t2 as a new second strength value TS again. After the time point t2, the delay value CD sharply drops, meaning that the touch sensor is in a no-touch state. Thus, the strength determiner 320 does not vary the second strength value TS after the time point t2.

As described above, when the power voltage is initially applied or the touch sensor is reset, each of the first and second strength values NTS and TS becomes 0. In this case, the first strength value NTS is initialized to the present delay value CD (refer to step S12 in FIG. 6), and the second strength value TS is initialized to the value obtained by adding the fourth value D4 to the first strength value NTS (refer to step S22 in FIG. 8). Hence, when the power voltage is initially applied or the touch sensor is reset, a threshold value may be calculated based on the initialized first and second strength values NTS and TS and compared with the delay value CD to determine whether the touch sensor is in a touch state (refer to step S13 in FIG. 6 and step S23 in FIG. 8).

Although FIGS. 6 through 9 illustrate examples of a delay-type touch sensor, the present invention may also be applied to a touch sensor capable of measuring impedance, as described above. In this case, the strength determiner 320 determines the first and second strength values NTS and TS using a value corresponding to the measured impedance instead of the delay value CD corresponding to the delay time difference between the reference signal “ref” and the sensing signal “sen”, as described above.

FIG. 10 shows the constitution of the decider 330 of the touch determiner 300 shown in FIG. 4 according to an exemplary embodiment of the present invention. The decider 330 includes a threshold value calculator 331 and a touch decider 332.

Functions of the blocks shown in FIG. 10 will now be described. The threshold value calculator 331 receives the first and second strength values NTS and TS from the strength determiner 320, calculates a threshold value Th_value, and outputs the threshold value Th_value. The threshold value Th_value may be obtained using Equation 1:

$$Th\_value = \frac{3}{4} \times TS + \frac{1}{4} \times NTS . \qquad ( 1 )$$

The touch decider 332 receives the threshold value Th_value output by the threshold value calculator 331 and the delay value CD output by the filter unit 310, determines whether the touch sensor is in a touch state, and outputs the touch signal “touch” indicating whether touch has occurred.

For instance, the touch decider 332 may decide that touch has occurred when the delay value CD is greater than the threshold value Th_value by a predetermined third time or longer, and decide that no touch has occurred when the delay value CD is less than the threshold value Th_value by a predetermined fourth time or longer. In this case, in order to prevent the touch decider 332 from mistaking no touch for touch due to noise, the third time may be controlled to be longer than the fourth time. For example, the third time may be 10 ms, and the fourth time may be 4 ms. Alternatively, the touch decider 332 may decide that touch has occurred when the delay value CD is greater than a value obtained by adding a predetermined first offset value Dh1 to the threshold value Th_value, and decide that no touch has occurred when the delay value CD is less than a value obtained by subtracting a predetermined second offset value Dh2 from the threshold value Th_value. Alternatively, the touch decider 332 may decide whether touch has occurred using a combination of the foregoing two methods.

In another case, the touch decider 332 may be simply constructed to decide that touch has occurred when the delay value CD is greater than the threshold value Th_value and that no touch has occurred when the delay value CD is less than the threshold value Th_value.

Although not shown in the drawings, the threshold value calculator 331 may further output a first threshold value Th_value1 and a second threshold value Th_value2. The first threshold value Th_value1 may be obtained by adding the first offset value Dh1 to the threshold value Th_value, while the second threshold value Th_value2 may be obtained by subtracting the second offset value Dh2 from the threshold value Th_value. The first offset value Dh1 may be equal to the second offset value Dh2. Alternatively, the first threshold value Th_value1 may be obtained by adding the first offset value Dh1 to the first strength value NTS, while the second threshold value Th_value2 may be obtained by subtracting the second offset value Dh2 from the second strength value TS.

Although not shown in the drawings, the touch decider 332 may directly receive the first and second strength values NTS and TS from the strength determiner 320, receive the delay value CD from the filter 310, decide that touch has occurred when the delay value CD is greater than the first strength value NTS by a predetermined value or more in state of no touch, and decide that no touch has occurred when the delay value CD is less than the second strength value TS by a predetermined value or more in state of touch. When the touch decider 332 decides whether touch has occurred only in the above-described manner, the threshold value calculator 331 may be omitted from the decider 330 shown in FIG. 10. Also, the touch decider may decide whether touch has occurred using a combination of the above-described methods.

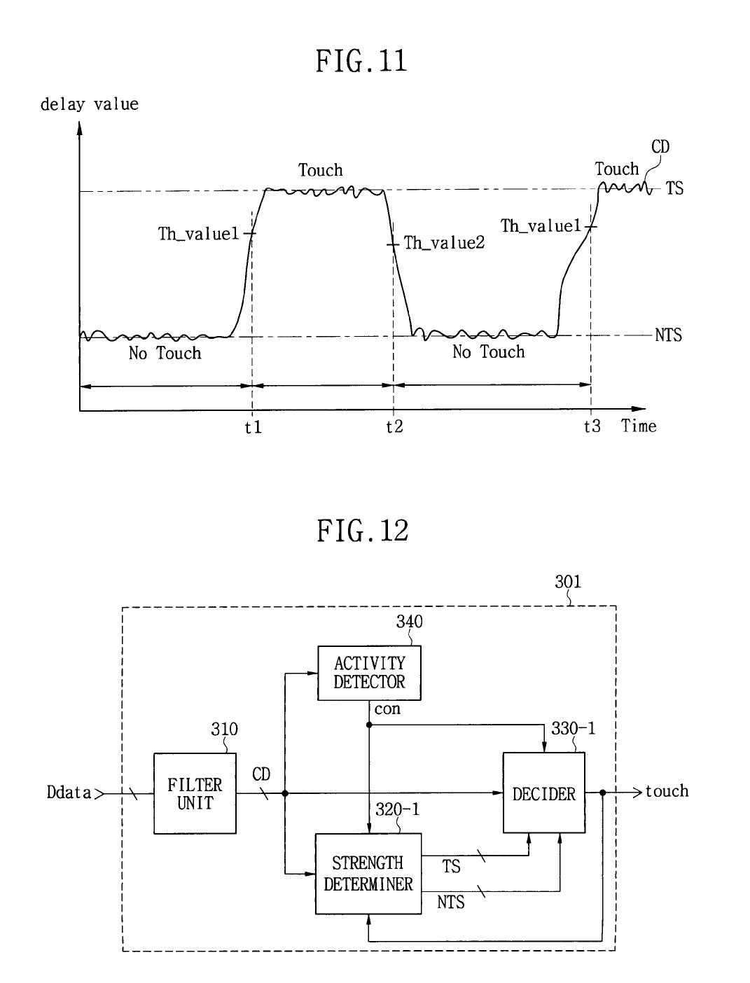

FIG. 11 is a timing diagram illustrating operation of the decider 330 shown in FIG. 10. In FIG. 11, the first strength value NTS is illustrated with an alternating long-short dashed line, the second strength value TS is illustrated with a two-point chain line, and the delay value CD is illustrated with a solid line. The decider 330 may decide that touch has occurred when the delay value CD is greater than the first threshold value Th_value1, and decide that touch has not occurred when the delay value CD is less than the second threshold value Th_value2.

Operation of the decider 330 shown in FIG. 10 will now be described with reference to FIG. 11.

Since the delay value CD is less than the first threshold value Th_value1 before a time point t1, the decider 330 decides that no touch has occurred and outputs a corresponding touch signal “touch”, for an example of logic-low. Since the delay value CD becomes greater than the first threshold value Th_value1 at the time point t1, the decider 330 decides that touch has occurred and outputs a corresponding touch signal “touch”, for an example of logic-high. Since the delay value CD is greater than the second threshold value Th_value2 between the time point t1 and a time point t2, the decider 330 decides that touch has occurred and outputs the corresponding touch signal “touch”. Since the delay value CD becomes less than the second threshold value Th_value2 at the time point t2, the decider 330 decides that no touch has occurred and outputs the corresponding touch signal “touch”. Since the delay value CD is less than the first threshold value Th_value1 between the time point t2 and a time point t3, the decider 330 decides that no touch has occurred and outputs the corresponding touch signal “touch”. Since the delay value CD becomes greater than the first threshold value Th_value1 at the time point t3, the decider 330 decides that touch has occurred and outputs the corresponding touch signal “touch”.

The first and second threshold values Th_value1 and Th_value2 may be calculated using the first and second strength values NTS and TS in the above-described manner.

FIG. 12 shows the constitution of the touch determiner of the touch sensor according to another exemplary embodiment of the present invention. A touch determiner 301 includes a filter unit 310, a strength determiner 320-1, a decider 330-1, and an activity detector 340.

Functions of the blocks shown in FIG. 12 will now be described.

The filter unit 310 performs the same function as described with reference to FIGS. 4 and 5. The strength determiner 320-1 calculates and outputs first and second strength values NTS and TS in the same manner as described with reference to FIGS. 4 and 6 through 9 and operates in response to a control signal “con” output by the activity detector 340. The decider 330-1 decides whether touch has occurred and outputs a touch signal “touch” indicating whether touch has occurred in the same manner as described with reference to FIGS. 4, 10, and 11. The activity detector 340 receives the delay value CD output by the filter unit 310, determines whether the touch sensor is active based on variation in the delay value CD, and outputs the control signal “con” based on the determination result. For example, when the delay value CD is within a predetermined range for a predetermined time, the activity detector 340 may determine that the touch sensor is inactive and output the corresponding control signal “con”.

That is, the touch determiner 301 shown in FIG. 12, according to another exemplary embodiment of the present invention, may further include the activity detector 340, which may output the control signal “con” depending on whether the touch sensor is active or not in response to the variation in the delay value CD. Also, the strength determiner 320-1 and/or the decider 330-1 may receive the control signal “con” from the activity detector 340 and operate only when the touch sensor is active, thereby minimizing power consumption.

Although not shown in the drawings, the activity detector 340 may receive first filtered data “data1” output by a first linear filter 311 of the filter unit 310. or second filtered data “data2” output by a nonlinear filter 312 of the filter unit 310, and determine whether the touch sensor is active.

Although not shown in the drawings, the control signal “con” output by the activity detector 340 may be transmitted out of the touch sensor to control operation of an input apparatus including the touch sensor. For example, when the touch sensor is inactive, the activity detector 340 may output the control signal “con” to enable operation of only blocks sending a preamble for transmission/reception clock synchronization among blocks of the input apparatus including the touch sensor. In this case, reduction of response speed due to power-down of the input apparatus may be prevented, thereby improving the response speed of the input apparatus.

Although not shown in the drawings, the activity detector 340 may receive the touch signal “touch” from the decider 330-1 and output a wake-up signal for waking up an input apparatus including the touch sensor. For instance, when the activity detector 340 detects tapping in response to the touch signal “touch”, that is, when a touch is repeated more than a predetermined number of times, the activity detector 340 may output the wake-up signal for waking up the input apparatus.

Although the example of a touch sensor is described above, the present invention may also be applied to a proximity sensor. The proximity sensor detects an object coming close to itself or the presence or absence of an object within close range without physical contact. Among various proximity sensors, a proximity sensor capable of sensing variation in impedance to recognize proximity is structurally similar to the touch sensor capable of sensing impedance to recognize touch. Thus, the touch sensor capable of sensing impedance may also be used as a proximity sensor by greatly increasing the sensitivity of the touch sensor. Even if the sensitivity of the touch sensor is not greatly increased, a proximity sensor may be configured with a plurality of touch sensors that are electrically connected to one another to increase a sensing area. When the present invention is applied to a proximity sensor, the first strength value NTS or the second strength value TS may vary depending not on touch but on proximity of an object, and the proximity of the object may be determined based on a threshold value obtained using the first and second strength values NTS and TS.

While the present invention has been shown and described with reference to certain exemplary embodiments thereof, it will be understood by those skilled in the art that various changes in form and details may be made therein without departing from the spirit and scope of the invention as defined by the appended claims. According to the present invention, a sensor can recognize touch with a given sensitivity without performing a tuning operation in consideration of environment changes such as interference noise, detecting location, cover thickness, and/or touch pad type.

What is claimed is:

1. A sensor comprising:
a sensing data output unit configured to output sensing data that varies depending on touch or proximity of an object; and
a determiner configured to compare a threshold value with the sensing data to recognize touch or proximity, vary a first strength value indicating the sensing data in a state of no touch or no proximity and a second strength value indicating the sensing data in a state of touch or proximity, vary the threshold value using the first and second strength values, and output an output signal indicating touch or proximity.

2. The sensor according to claim 1, wherein the sensing data output unit measures impedance that varies depending on touch or proximity and outputs a value corresponding to the measured impedance as the sensing data.

3. The sensor according to claim 1, wherein the sensing data output unit comprises:
a sensing signal output unit configured to output a reference signal and a sensing signal delayed with respect to the reference signal depending on touch or proximity; and
a delay time measurement unit configured to detect a delay time difference between the sensing signal and the reference signal and output delay data corresponding to the delay time difference as the sensing data.

4. The sensor according to claim 3, wherein the sensing signal output unit comprises:
a reference clock generator configured to generate a reference clock signal;
a reference signal generator configured to receive the reference clock signal and output the reference signal; and
a sensing signal generator including a pad and configured to delay the reference clock signal when the object touches or approaches the pad and output the sensing signal. 10

5. The sensor according to claim 3, wherein the delay time measurement unit comprises:
a delay chain unit including a plurality of delay elements connected in cascade and configured to output, in response to the reference signal, a plurality of delay signals having different delay times and an iteration counting signal indicating the number of times the reference signal is fed back;
an edge detector configured to output a reset signal in response to the reference signal, output a counting stop signal in response to the sensing signal, and output a code signal corresponding to the number of edges of the delay signals; and
a decoder configured to decode the iteration counting signal and the code signal and output the delay data corresponding to the delay time difference between the reference signal and the sensing signal.

6. The sensor according to claim 5, wherein the delay chain unit comprises:
a switch configured to perform a logical AND operation on the delay signal, the counting stop signal, and a feedback signal and output a first delay signal of the delay signals;
a delay chain including the delay elements configured to receive the first delay signal, delay the first delay signal, and each output a corresponding one of the delay signals;
an inverter configured to invert a final delay signal output by a final delay element of the delay elements and output the feedback signal; and
a counter configured to be reset in response to the reset signal, configured to count edges of the feedback signal to generate the iteration counting signal and configured to output the iteration counting signal to the decoder in response to the counting stop signal.

7. The sensor according to claim 1, wherein the determiner comprises:
a filter unit configured to receive the sensing data and output a sensing value;
a strength determiner configured to vary and output the first strength value without varying the second strength value in a state of no touch or no proximity using the sensing value and to vary and output the second strength value without varying the first strength value in a state of touch or proximity using the sensing value; and
a decider configured to receive the first and second strength values to calculate the threshold value, compare the threshold value with the sensing value to decide whether there is touch or proximity, and output the output signal.

8. The sensor according to claim 7, wherein the filter unit comprises a linear filter configured to receive the sensing data at a first sampling rate, remove noise from the sensing data, and output the sensing value.

9. The sensor according to claim 7, wherein the filter unit comprises:
a linear filter configured to receive the sensing data at a first sampling rate, remove noise from the sensing data, and output first filtered data; and
a nonlinear filter configured to receive the first filtered data, restrict variation within a sample or combine a plurality of samples, and output the sensing value.

10. The sensor according to claim 7, wherein the filter unit comprises:
a first linear filter configured to receive the sensing data at a first sampling rate, remove noise from the sensing data, and output first filtered data; and
a second linear filter configured to receive the first filtered data at a second sampling rate that is lower than the first sampling rate, remove noise from the first filtered data, and output the sensing value.

11. The sensor according to claim 7, wherein the filter unit comprises:
a first linear filter configured to receive the sensing data at a first sampling rate, remove noise from the sensing data, and output first filtered data;
a nonlinear filter configured to receive the first filtered data, restrict variation within a sample or combine a plurality of samples, and output second filtered data; and
a second linear filter configured to receive the second filtered data at a second sampling rate that is lower than the first sampling rate, remove noise from the second filtered data, and output the sensing value.

12. The sensor according to claim 11, wherein each of the first and second linear filters is a low-pass filter (LPF).

13. The sensor according to claim 11, wherein each of the first and second linear filters is a band-pass filter (BPF).

14. The sensor according to claim 7, wherein the strength determiner changes the first strength value to the sensing value when the first strength value is 0, and changes the second strength value to a value obtained by adding a predetermined first value to the sensing value when the second strength value is 0.

15. The sensor according to claim 14, wherein, in a state of no touch or no proximity, the strength determiner maintains the first strength value when the sensing value varies during a predetermined first time, and changes the first strength value to the sensing value when the sensing value does not vary during the first time.

16. The sensor according to claim 14, wherein, in a state of no touch or no proximity, the strength determiner maintains the first strength value when the second strength value is less than a predetermined second value, and changes the first strength value to the sensing value when the second strength value is greater than the second value.

17. The sensor according to claim 14, wherein, in a state of no touch or no proximity, the strength determiner maintains the first strength value when a difference between the first strength value and the sensing value is less than a predetermined third value, and changes the first strength value to the sensing value when the difference between the first strength value and the sensing value is greater than the third value.

18. The sensor according to claim 14, wherein, in a state of no touch or no proximity, the strength determiner maintains the first strength value when the sensing value varies during a predetermined first time, changes the first strength value to a value obtained by adding a predetermined fourth value to the first strength value when the sensing value does not vary during the first time and the first strength value is greater than the sensing value, and changes the first strength value to a value obtained by subtracting the fourth value from the first strength value when the sensing value does not vary during the first time and the first strength value is less than the sensing value.

19. The sensor according to claim 14, wherein, in a state of no touch or no proximity, the strength determiner maintains the first strength value when the second strength value is less than a predetermined second value, changes the first strength value to a value obtained by adding a predetermined fourth value to the first strength value when the second strength value is greater than the second value and the first strength value is greater than the sensing value, and changes the first strength value to a value obtained by subtracting the fourth value from the first strength value when the second strength value is greater than the second value and the first strength value is less than the sensing value.

20. The sensor according to claim 14, wherein, in a state of no touch or no proximity, the strength determiner maintains the first strength value when a difference between the first strength value and the sensing value is less than a predetermined third value, changes the first strength value to a value obtained by adding a predetermined fourth value to the first strength value when the difference between the first strength value and the sensing value is greater than the third value and the first strength value is greater than the sensing value, and changes the first strength value to a value obtained by subtracting the fourth value from the first strength value when the difference between the first strength value and the sensing value is greater than the third value and the first strength value is less than the sensing value.

21. The sensor according to claim 14, wherein, in a state of touch or proximity, the strength determiner maintains the second strength value when the sensing value varies during a predetermined second time, and changes the second strength value to the sensing value when the sensing value does not vary during the second time.

22. The sensor according to claim 21, wherein, in a state of touch or proximity, the strength determiner changes the second strength value to the sensing value when the second strength value is greater than a value obtained by adding a predetermined fifth value to the first strength value, and changes the second strength value to the value obtained by adding the fifth value to the first strength value when the second strength value is less than the value obtained by adding the fifth value to the first strength value.

23. The sensor according to claim 7, wherein the decider comprises:
a threshold value calculator configured to receive the first and second strength values and calculate a threshold value; and
a touch decider configured to compare the threshold value with the sensing value to decide whether there is touch or proximity and output the output signal based on the decision result.

24. The sensor according to claim 23, wherein the threshold value includes a first threshold value and a second threshold value,
the threshold value calculator outputs the first threshold value obtained by adding a predetermined first offset value to the threshold value and the second threshold value obtained by subtracting a predetermined second offset value from the threshold value, and
the touch decider decides that there is touch or proximity when the sensing value becomes greater than the first threshold value in a state of no touch or no proximity, and decides that there is no touch or no proximity when the sensing value becomes less than the second threshold value in a state of touch or proximity.

25. The sensor according to claim 23, wherein the decider decides that there is touch or proximity when the sensing value is greater than the threshold value for a third time in a state of no touch or no proximity, and decides that there is no touch or no proximity when the sensing value is less than the threshold value for a fourth time that is shorter than the third time in a state of touch or proximity.

26. The sensor according to claim 7, wherein the decider receives the first strength value, the second strength value, and the sensing value, decides that there is touch or proximity when the sensing value becomes greater than a value obtained by adding a predetermined sixth value to the first strength value in a state of no touch or no proximity, decides that there is no touch or no proximity when the sensing value becomes less than a value obtained by subtracting a predetermined seventh value from the second strength value in a state of touch or proximity, and outputs the output signal based on the decision result.

27. The sensor according to claim 7, wherein the determiner further comprises an activity detector configured to receive the sensing value, determine that the sensor is inactive when the sensing value is within a predetermined range for a predetermined time, and enable a control signal,
wherein the strength determiner and/or the decider stop operating when the control signal is enabled.

28. The sensor according to claim 27, wherein the sensor externally outputs the control signal and controls operation of an external input apparatus.

29. The sensor according to claim 7, wherein the determiner further comprises an activity detector configured to receive the output signal, detect if tapping occurs, and generate a wake-up signal when tapping is detected.

30. The sensor according to claim 29, wherein the sensor externally outputs the wake-up signal and wakes up an external input apparatus.

31. A sensing method comprising:
a sensing value calculating step of calculating a sensing value that varies depending on touch or proximity of an object;
an initialization step of changing the first strength value to the sensing value when a first strength value is 0, and changing the second strength value to a value obtained by adding a predetermined first value to the sensing value when a second strength value is 0;
a first strength value varying step of receiving the sensing value and varying the first strength value in a state of no touch or no proximity;
a second strength value varying step of receiving the sensing value and varying the second strength value in a state of touch or proximity;
a threshold value calculating step of receiving the first and second strength values and calculating a threshold value; and
a recognition step of comparing the sensing value with the threshold value and recognizing touch or proximity.

32. The method according to claim 31, wherein the sensing value corresponds to impedance that varies depending on touch or proximity of the object.

33. The method according to claim 31, wherein the sensing value corresponds to a delay time difference between a reference signal and a sensing signal that is delayed with respect to the reference signal when the object is touched or approached.

34. The method according to claim 31, wherein the first strength value varying step comprises maintaining the first strength value when the sensing value varies during a predetermined first time, and changing the first strength value to the sensing value when the sensing value does not vary during the first time.

35. The method according to claim 31, wherein the first strength value varying step comprises maintaining the first strength value when the second strength value is less than a predetermined second value, and changing the first strength value to the sensing value when the second strength value is greater than the second value.

36. The method according to claim 31, wherein the first strength value varying step comprises maintaining the first strength value when a difference between the first strength value and the sensing value is less than a predetermined third value, and changing the first strength value to the sensing value when the difference between the first strength value and the sensing value is greater than the third value.

37. The method according to claim 31, wherein the first strength value varying step comprises maintaining the first strength value when the sensing value varies during a predetermined first time, changing the first strength value to a value obtained by adding a predetermined fourth value to the first strength value when the sensing value does not vary during the first time and the first strength value is greater than the sensing value, and changing the first strength value to a value obtained by subtracting the fourth value from the first strength value when the sensing value does not vary during the first time and the first strength value is less than the sensing value.

38. The method according to claim 31, wherein the second strength value varying step comprises maintaining the second strength value when the sensing value varies during a predetermined second time and changing the second strength value to the sensing value when the sensing value does not vary during the second time.

39. The method according to claim 38, wherein the second strength value varying step comprises changing the second strength value to the sensing value when the second strength value is greater than a value obtained by adding a predetermined fifth value to the first strength value, and changing the second strength value to the value obtained by adding the fifth value to the first strength value when the second strength value is less than the value obtained by adding the fifth value to the first strength value.

40. The method according to claim 31, wherein the recognition step comprises recognizing the state of touch or proximity when the sensing value is greater than the threshold value for a third time in a state of no touch or no proximity, and recognizing the state of no touch or no proximity when the sensing value is less than the threshold value for a fourth time that is shorter than the third time.

41. The method according to claim 40, wherein the threshold value includes a first threshold value and a second threshold value,
wherein the threshold value calculating step comprises calculating the first threshold value by adding a predetermined first offset value to the threshold value and calculating the second threshold value by subtracting a predetermined second offset value from the threshold value, and
wherein the recognition step comprises recognizing the state of touch or proximity when the sensing value becomes greater than the first threshold value in a state of no touch or no proximity, and recognizing the state of no touch or no proximity when the sensing value becomes less than the second threshold value in a state of touch or proximity.

42. The method according to claim 31, wherein the threshold value includes a first threshold value and a second threshold value,
wherein the threshold value calculating step comprises calculating the first threshold value by adding a predetermined first offset value to the first strength value and calculating the second threshold value by subtracting a predetermined second offset value from the second strength value, and
wherein the recognition step comprises recognizing the state of touch or proximity when the sensing value becomes greater than the first threshold value in a state of no touch or no proximity, and recognizing the state of no touch or no proximity when the sensing value becomes less than the second threshold value in a state of touch or proximity.

43. A filter of a sensor comprising:
a first linear filter configured to receive sensing data that varies depending on touch or proximity at a first sampling rate, remove noise from the sensing data, and output first filtered data; and
a second filter connected in cascade to the first linear filter and configured to receive the first filtered data, filter the first filtered data, and output second filtered data.

44. The filter according to claim 43, wherein the second filter is a nonlinear filter configured to receive the first filtered data, restrict variation within a sample or combine a plurality of samples, and output the second filtered data.

45. The filter according to claim 43, wherein the second filter is a second linear filter configured to receive the first filtered data at a second sampling rate that is lower than the first sampling rate, remove noise from the first filtered data, and output the second filtered data.

46. The filter according to claim 44, further comprising a second linear filter configured to receive the second filtered data at a second sampling rate that is lower than the first sampling rate, remove noise from the second filtered data, and output the sensing value.

47. The filter according to claim 46, wherein each of the first and second linear filters is a low-pass filter (LPF).

48. The filter according to claim 46, wherein each of the first and second linear filters is a band-pass filter (BPF).
